(19) United States
(12) Patent Application Publication
(10) Pub. No.: US 2024/0224597 A1
(43) Pub. Date: Jul. 4, 2024

(54) DISPLAY APPARATUS

(71) Applicant: Samsung Display Co., Ltd., Yongin-si (KR)

(72) Inventors: Hyeongseok Kim, Yongin-si (KR); Junhyun Park, Yongin-si (KR); Heejean Park, Yongin-si (KR); Sunhwa Lee, Yongin-si (KR); Danwon Lim, Yongin-si (KR); Mukyung Jeon, Yongin-si (KR)

(73) Assignee: Samsung Display Co., Ltd., Yongin-si (KR)

(21) Appl. No.: 18/400,339

(22) Filed: Dec. 29, 2023

(30) Foreign Application Priority Data
Dec. 30, 2022 (KR) 10-2022-0191036

(51) Int. Cl. H10K 59/121; G09G 3/3233; H10K 59/131

(52) U.S. Cl. CPC H10K 59/1216; G09G 3/3233; H10K 59/131; G09G 2300/0819; G09G 2300/0852; G09G 2310/0262

(57) ABSTRACT

A display apparatus includes a substrate, a first transistor including a first semiconductor layer on the substrate and a first electrode overlapping the first semiconductor layer, a first capacitor including the first electrode and a second electrode, the second electrode overlapping the first electrode, a second capacitor including the second electrode and a third electrode, the third electrode overlapping the second electrode, a first connection electrode and a second connection electrode disposed on the third electrode, wherein the third electrode includes a first opening, and a portion of the first connection electrode and a portion of the second connection electrode are adjacent to each other, are spaced apart from each other, and overlap the first opening.

### CROSS-REFERENCE TO RELATED APPLICATION(S)

This application claims priority to and benefits of Korean Patent Application No. 10-2022-0191036 under 35 U.S.C. § 119, filed on Dec. 30, 2022, in the Korean Intellectual Property Office, the entire contents of which are incorporated herein by reference.

### BACKGROUND

### 1. Technical Field

One or more embodiments relate to a display apparatus.

### 2. Description of the Related Art

Display apparatuses display data visually. Display apparatuses may be used as displays for small products, such as mobile phones, or displays for large products, such as televisions.

A display apparatus includes pixels that receive electrical signals and emit light so as to display images to the outside. A pixel includes a display element. For example, an organic light-emitting display apparatus includes an organic light-emitting diode (OLED) as a display element. In general, an organic light-emitting display apparatus includes a thin-film transistor and an OLED on a substrate, and the OLED emits light by itself.

Recently, as the usage of display apparatuses has diversified, various attempts have been made to improve the quality of display apparatuses.

### SUMMARY

One or more embodiments provide a display apparatus capable of improving resolution.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, a display apparatus may include a substrate, a first transistor including a first semiconductor layer on the substrate and a first electrode overlapping the first semiconductor layer, a first capacitor including the first electrode and a second electrode, the second electrode overlapping the first electrode, a second capacitor including the second electrode and a third electrode, the third electrode overlapping the second electrode, a first connection electrode and a second connection electrode disposed on the third electrode, wherein the third electrode may include a first opening, and a portion of the first connection electrode and a portion of the second connection electrode may be adjacent to each other, may be spaced apart from each other, and may overlap the first opening.

In an embodiment, the first connection electrode may be electrically connected to the first electrode, and the second connection electrode may be electrically connected to the second electrode.

In an embodiment, the second electrode may include a second opening overlapping the first opening in a direction perpendicular to an upper surface of the substrate, and a portion of the first connection electrode may overlap the second opening.

In an embodiment, a size of the first opening may be greater than a size of the second opening.

In an embodiment, a size of the first opening may be substantially equal to or greater than twice a size of the second opening.

In an embodiment, the second electrode may be disposed above the first electrode, the third electrode may be disposed above the second electrode, and the first connection electrode and the second connection electrode may be disposed above the third electrode.

In an embodiment, the first connection electrode and the second connection electrode may be disposed on a same layer.

In an embodiment, the display apparatus may further include a second semiconductor layer disposed above the third electrode, and a second transistor including a gate electrode disposed above the second semiconductor layer, the gate electrode overlapping the second semiconductor layer.

In an embodiment, the first semiconductor layer may include a silicon semiconductor material, and the second semiconductor layer may include an oxide semiconductor material.

In an embodiment, the first connection electrode and the second connection electrode may be disposed above the second semiconductor layer.

In an embodiment, the second connection electrode may electrically connect the second electrode to the second semiconductor layer.

In an embodiment, the second semiconductor layer may include a first active pattern layer and a second active pattern layer, the first active pattern layer may be electrically connected to the second electrode through the second connection electrode, and the second active pattern layer may be electrically connected to the first electrode through the first connection electrode.

According to one or more embodiments, a display apparatus may include a substrate, a first semiconductor layer disposed above the substrate, a first gate layer disposed above the first semiconductor layer, the first gate layer including a first electrode, a second gate layer disposed above the first gate layer, the second gate layer including a second electrode overlapping the first electrode in a direction toward an upper surface of the substrate, a connection conductive layer disposed above the second gate layer, the connection conductive layer including a third electrode overlapping the second electrode and having a first opening, and a connection electrode layer disposed above the connection conductive layer, the connection electrode layer including a first connection electrode and a second connection electrode, wherein a portion of the first connection electrode and a portion of the second connection electrode may be adjacent to each other, may be spaced apart from each other, and may overlap the first opening.

In an embodiment, the second electrode may include a second opening overlapping the first opening in a direction perpendicular to the upper surface of the substrate, and a portion of the first connection electrode may overlap the second opening.

In an embodiment, the first connection electrode may be electrically connected to the first electrode through the first opening and the second opening, and the second connection electrode may be electrically connected to the second electrode through the second opening.

In an embodiment, a size of the first opening may be greater than a size of the first opening.

In an embodiment, a size of the first opening may be substantially equal to or greater than twice a size of the second opening.

In an embodiment, the display apparatus may further include a second semiconductor layer disposed above the connection conductive layer and disposed below the connection electrode layer, and a third gate electrode layer disposed above the second semiconductor layer and disposed below the connection electrode layer.

In an embodiment, the first semiconductor layer may include a silicon semiconductor material, and the second semiconductor layer may include an oxide semiconductor material.

In an embodiment, the second semiconductor layer may include a first active pattern layer and a second active pattern layer, the first active pattern layer may be electrically connected to the second electrode through the second connection electrode, and the second active pattern layer may be electrically connected to the first electrode through the first connection electrode.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view illustrating a display apparatus according to an embodiment;

FIG. 2 is a schematic side view illustrating the display apparatus of FIG. 1;

FIG. 3 is a schematic diagram of an equivalent circuit of a pixel included in the display apparatus of FIG. 1;

FIG. 4 is a schematic layout diagram illustrating positions of transistors and capacitors in pixels included in the display apparatus of FIG. 1;

FIGS. 5 to 17 are schematic layout diagrams illustrating the layer-based configurations of transistors and capacitors in the display apparatus illustrated in FIG. 4; and

FIG. 18 is a schematic cross-sectional view of the display apparatus taken along line I-I′ of FIG. 4, according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

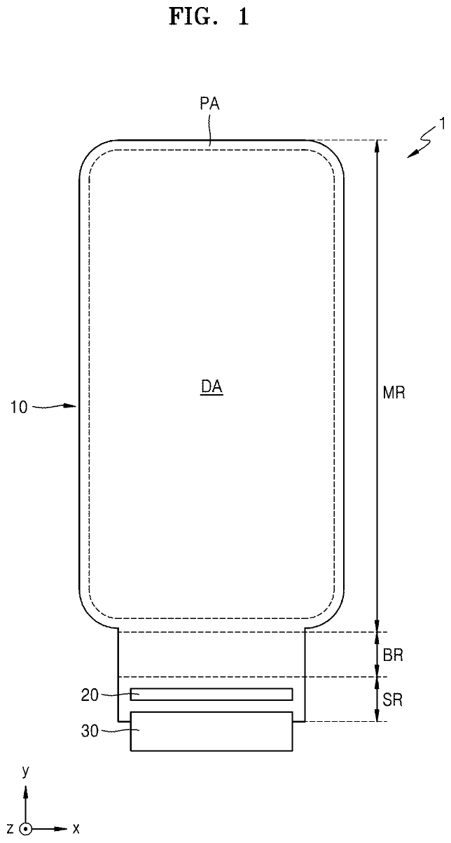

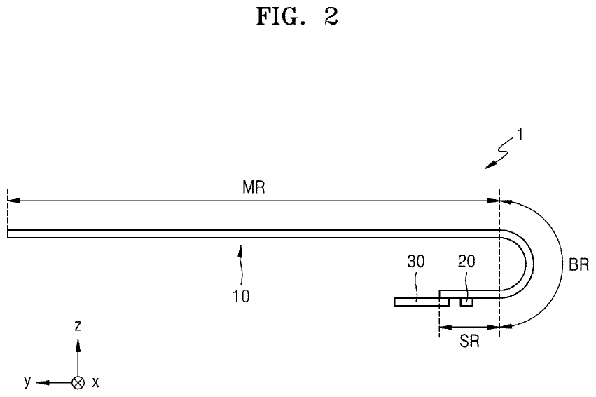

FIG. 1 is a schematic plan view illustrating a display apparatus 1 according to an embodiment, and FIG. 2 is a schematic side view illustrating the display apparatus 1 of FIG. 1. As illustrated in FIG. 2, a portion of the display apparatus 1 according to an embodiment may be bent. However, for descriptive convenience, FIG. 1 illustrates that the display apparatus 1 is not bent.

As illustrated in FIGS. 1 and 2, the display apparatus 1 according to an embodiment may include a display panel 10. As the display apparatus 1, any types of display apparatus may be used as long as the display apparatus includes the display panel 10. For example, the display apparatus 1 may be a variety of products, such as smartphones, tablets, laptops, televisions, or billboards.

The display panel 10 may include a display area DA and a peripheral area PA outside the display area DA. The display area DA may display an image, and pixels may be arranged in the display area DA. When viewed from a direction substantially perpendicular to the display panel 10, the display area DA may have various shapes, such as a circular shape, an elliptical shape, a polygonal shape, or a specific figure shape. FIG. 1 illustrates that the display area DA has substantially a rectangular shape with round corners.

The peripheral area PA may be outside the display area DA. A width of a portion of the peripheral area PA (e.g., in the x-axis direction) may be narrower than a width of the display area DA (e.g., in the x-axis direction). Due to such a structure, at least a portion of the peripheral area PA may be readily bent, as will be described below.

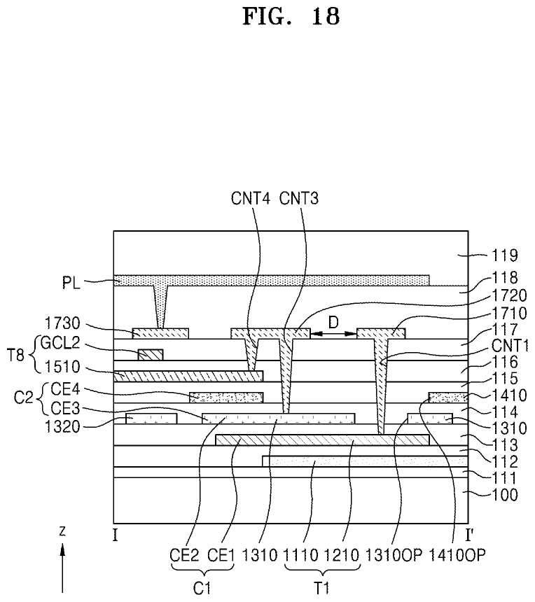

As the display panel 10 includes a substrate (see 100 of FIG. 18), the substrate 100 may include the display area DA and the peripheral area PA as described above. Hereinafter, for descriptive convenience, the substrate 100 will be described as including the display area DA and the peripheral area PA.

The display panel 10 may include a main region MR, a bending region BR outside the main region MR, and a sub-region SR, the main region MR and the sub-region SR may be positioned on opposite sides of the bending region BR. In the bending region BR, the display panel 10 may be bent as illustrated in FIG. 2. Accordingly, when viewed in the z-axis direction, at least a portion of the sub-region SR may overlap the main region MR. For example, embodiments are not limited to the display apparatus 1 that is bent, and may also be applied to the display apparatus 1 that is not bent. The sub-region SR may be a non-display area to be described below. By bending the display panel 10 in the bending region BR, the non-display area may not be recognized when the display apparatus 1 is viewed in the negative z-axis direction, or in case that the non-display area is recognized, the recognized area thereof may be minimized.

A driving chip 20 may be arranged in the sub-region SR of the display panel 10. The driving chip 20 may include an integrated circuit that drives the display panel 10. The integrated circuit may be a data driving integrated circuit that generates a data signal, but embodiments are not limited thereto.

The driving chip 20 may be mounted on the sub-region SR of the display panel 10. Although the driving chip 20 is mounted on the same surface as the display surface of the display area DA, the driving chip 20 may be positioned on the rear surface of the main region MR as the display panel 10 is bent in the bending region BR.

A printed circuit board 30 or the like may be bonded to the end portion of the sub-region SR of the display panel 10. The printed circuit board 30 or the like may be electrically connected to the driving chip 20 or the like through pads on the substrate 100.

Hereinafter, an organic light-emitting display apparatus will be described as an example of the display apparatus 1 according to an embodiment, but embodiments are not limited thereto. In another example, the display apparatus 1 according to the disclosure may be an inorganic light-emitting display apparatus (or an inorganic electroluminescence (EL) display apparatus), a quantum dot light-emitting display apparatus, and the like. For example, an emission layer of a display element included in the display apparatus 1 may include an organic material or an inorganic material. For example, the display apparatus 1 may include an emission layer and a quantum dot layer positioned on a path of light emitted from the emission layer.

As described above, the display panel 10 may include the substrate 100. Various elements included in the display panel 10 may be positioned on the substrate 100. The substrate 100 may include glass, metals, or polymer resin. As described above, in case that the display panel 10 is bent in the bending region BR, the substrate 100 needs to be flexible or bendable. In this case, the substrate 100 may include, for example, polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. For example, various modifications are possible. For example, the substrate 100 may have a multilayer structure including two layers including polymer resin and a barrier layer including an inorganic material (e.g., silicon oxide, silicon nitride, silicon oxynitride, etc.) between the two layers.

Pixels may be arranged in the display area DA. Each of the pixels refers to a sub-pixel and may include a display element, such as an organic light-emitting diode (OLED). The pixel may emit, for example, red light, green light, blue light, or white light.

The pixel may be electrically connected to circuits arranged in the peripheral area PA. A scan driving circuit, an emission control driving circuit, terminals, a driving power supply line, and an electrode power supply line may be arranged in the peripheral area PA. The scan driving circuit may provide a scan signal to the pixel through a scan line. The emission control driving circuit may provide an emission control signal to the pixel through an emission control line. The terminals in the peripheral area PA of the substrate 100 may be exposed without being covered with an insulating layer, so as to be electrically connected to the printed circuit board 30. The terminals of the printed circuit board 30 may be electrically connected to the terminals of the display panel 10.

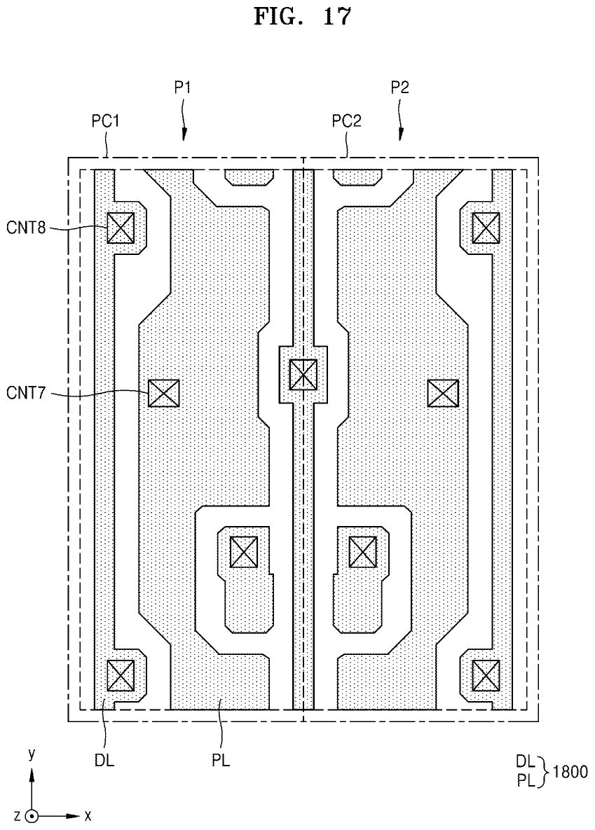

The printed circuit board 30 may transmit a signal or power from a controller to the display panel 10. A control signal, which is generated by the controller, may be transmitted to the scan driving circuit and the emission control driving circuit through the printed circuit board 30. For example, the controller may transmit a driving voltage ELVDD to the driving power supply line and provide a common voltage ELVSS to the electrode power supply line. The driving voltage ELVDD may be transmitted to each pixel through a driving voltage line (see PL of FIG. 17) connected to the driving power supply line, and the common voltage ELVSS may be transmitted to an opposite electrode of the pixel connected to the electrode power supply line. The electrode power supply line may have a loop shape with a side open, and may have a shape that partially surrounds the display area DA.

For example, the controller may generate a data signal, and the generated data signal may be transmitted to the pixel through the driving chip 20 and a data line (see DL of FIG. 17).

For reference, the term “line” may refer to a “wire.” This may be equally applied to embodiments and modifications as described below.

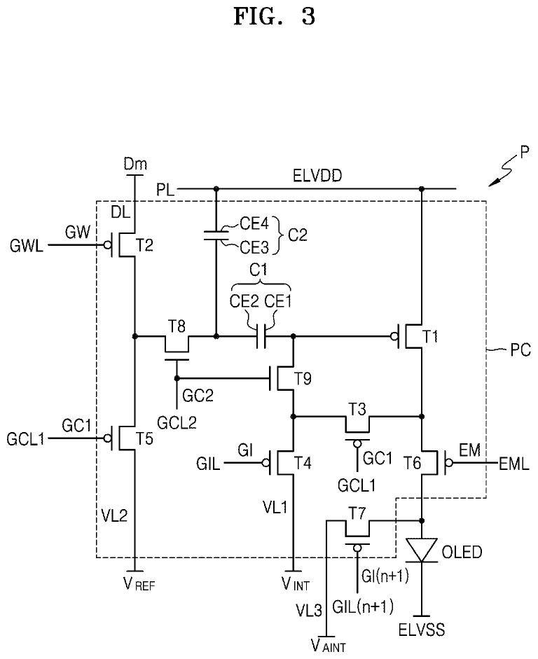

FIG. 3 is a schematic diagram of an equivalent circuit of a pixel P included in the display apparatus 1, according to an embodiment.

Referring to FIG. 3, the pixel P may include a pixel circuit PC and a display element electrically connected to the pixel circuit PC. The display element may be an organic light-emitting diode OLED having an anode electrode (or a pixel electrode) and a cathode electrode (or an opposite electrode).

For example, as illustrated in FIG. 3, the pixel circuit PC may include first to ninth transistors T1 to T9, a first capacitor C1, and a second capacitor C2. The first to ninth transistors T1 to T9, the first capacitor C1, and the second capacitor C2 may be connected to first to fifth scan lines GWL, GCL1, GIL, GIL(n+1), and GCL2 that transmit first to fifth scan signals GW, GC1, GI, GI(n+1), and GC2, a data line DL that transmits a data voltage Dm, an emission control line EML that transmits an emission control signal EM, a driving voltage line PL that transmits a first driving voltage (or driving voltage) ELVDD, a first voltage line VL1 that transmits a first initialization voltage V_{INT}, a second voltage line VL2 that transmits a reference voltage V_{REF}, a third voltage line VL3 that transmits a second initialization voltage V_{AINT}, and a common electrode to which a second driving voltage (or common voltage) ELVSS is applied.

The first transistor T1 may be a driving transistor in which an amount of a drain current is determined according to a gate-source voltage, and the second to ninth transistors T2 to T9 may each be a switching transistor that is turned on/off according to a gate-source voltage and substantially a gate voltage. The first to ninth transistors T1 to T9 may be formed as a thin-film transistor.

Some of the first to ninth transistors T1 to T9 may be formed as n-channel metal-oxide field effect transistor (MOSFET), e.g., NMOS, and the others thereof may be formed as p-channel MOSFET, e.g., PMOS. For example, as illustrated in FIG. 3, the eighth and ninth transistors T8 and T9 of the first to ninth transistors T1 to T9 may be formed as NMOS, and the others thereof may be formed as PMOS. In another example, only one of the first to ninth transistors T1 to T9 may be provided with NMOS and the others thereof may be provided with PMOS. In another example, all of the first to ninth transistors T1 to T9 may be formed as NMOS or PMOS.

The first capacitor C1 and the second capacitor C2 may be connected between the driving voltage line PL and a gate electrode of the first transistor T1. The first capacitor C1 may be a storage capacitor and may include a first lower electrode CE1 and a first upper electrode CE2. The first lower electrode CE1 of the first capacitor C1 may be connected to the gate electrode of the first transistor T1. The first upper electrode CE2 of the first capacitor C1 may be connected to a second lower electrode CE3 of the second capacitor C2. The second capacitor C2 may be a holding capacitor and may include the second lower electrode CE3 and a second upper electrode CE4. The second lower electrode CE3 of the second capacitor C2 may be connected to the first upper electrode CE2 of the first capacitor C1, and the second upper electrode CE4 of the second capacitor C2 may be connected to the driving voltage line PL.

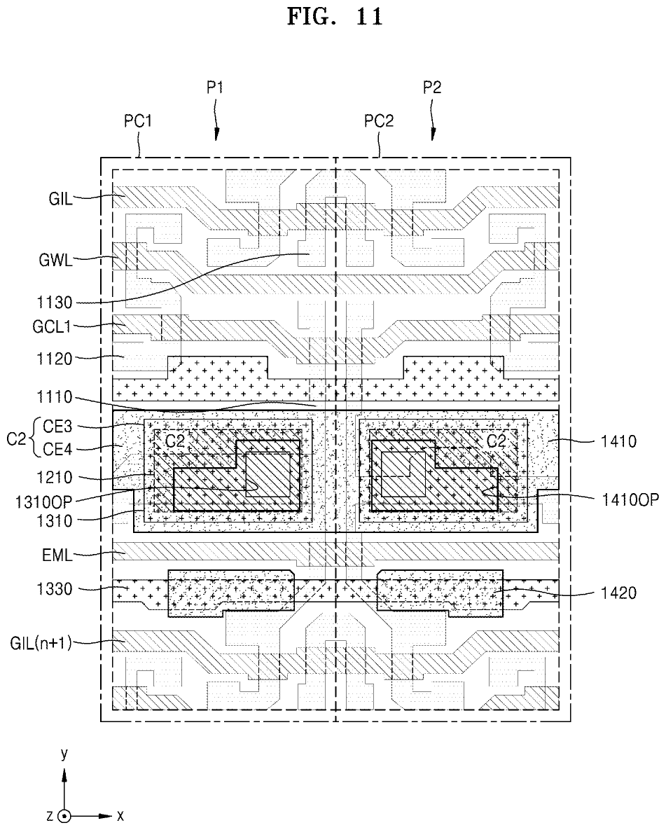

For example, as illustrated in FIGS. 11 and 18 to be described below, the first capacitor C1 and the second capacitor C2 may overlap each other. For example, the first upper electrode CE2 of the first capacitor C1 may function as the second lower electrode CE3 of the second capacitor C2. For example, the second lower electrode CE3 of the second capacitor C2 may function as the first upper electrode CE2 of the first capacitor C1.

Referring back to FIG. 3, the first transistor T1 may control the amount of driving current flowing from the driving voltage line PL to the organic light-emitting diode OLED according to the gate-source voltage of the first transistor T1. The gate electrode of the first transistor T1 may be connected to the first lower electrode CE1 of the first capacitor C1. A source electrode of the first transistor T1 may be connected to the driving voltage line PL. A drain electrode of the first transistor T1 may be connected to the organic light-emitting diode OLED through the sixth transistor T6.

The first transistor T1 may output the driving current to the organic light-emitting diode OLED according to the gate-source voltage of the first transistor T1. The amount of the driving current may be determined based on the difference between the gate-source voltage and a threshold voltage of the first transistor T1. The organic light-emitting diode OLED may receive the driving current from the first transistor T1 and emit light with brightness determined according to the amount of the driving current.

A gate electrode of the second transistor T2 may be connected to the first scan line GWL through which the first scan signal GW is transmitted. A source electrode of the second transistor T2 may be connected to the data line DL. A drain electrode of the second transistor T2 may be connected to the eighth transistor T8. The second transistor T2 may transmit the data voltage Dm to the eighth transistor T8 in response to the first scan signal GW.

The third transistor T3 may connect the drain electrode of the first transistor T1 to a source electrode of the ninth transistor T9 in response to the second scan signal GC1. The third transistor T3 may connect the drain electrode of the first transistor T1 to the gate electrode of the first transistor T1 through the ninth transistor T9.

The fourth transistor T4 may connect the first voltage line VL1 to the ninth transistor T9 in response to the third scan signal GI. The fourth transistor T4 may apply the first initialization voltage V_{INT} to the gate electrode of the first transistor T1 through the ninth transistor T9 in response to the third scan signal GI.

The fifth transistor T5 may connect the second voltage line VL2 to the eighth transistor T8 in response to the second scan signal GC1. The fifth transistor T5 may be connected to the first upper electrode CE2 of the first capacitor C1 (or the second lower electrode CE3 of the second capacitor C2) through the eighth transistor T8. The fifth transistor T5 may apply the reference voltage V_{REF} to the first upper electrode CE2 of the first capacitor C1 (or the second lower electrode CE3 of the second capacitor C2) through the eighth transistor T8 in response to the second scan signal GC1.

The sixth transistor T6 may connect the drain electrode of the first transistor T1 to the anode electrode of the organic light-emitting diode OLED in response to the emission control signal EM.

The seventh transistor T7 may connect the third voltage line VL3 to the anode electrode of the organic light-emitting diode OLED in response to the fourth scan signal GI(n+1). The fourth scan signal GI(n+1) may be a scan signal subsequent to the third scan signal GI. The seventh transistor T7 may apply the second initialization voltage V_{AINT} to the anode electrode of the organic light-emitting diode OLED in response to the fourth scan signal GI(n+1).

The eighth transistor T8 may connect the second transistor T2 or the fifth transistor T5 to the first upper electrode CE2 of the first capacitor C1 (or the second lower electrode CE3 of the second capacitor C2) in response to the fifth scan signal GC2. The eighth transistor T8 may apply the data voltage Dm or the reference voltage V_{REF} to the first upper electrode CE2 of the first capacitor C1 (or the second lower electrode CE3 of the second capacitor C2) in response to the fifth scan signal GC2.

The ninth transistor T9 may connect the third transistor T3 or the fourth transistor T4 to the gate electrode of the first transistor T1 in response to the fifth scan signal GC2. The ninth transistor T9 may apply the first initialization voltage V_{INT} to the gate electrode of the first transistor T1 or connect the drain electrode of the first transistor T1 to the gate electrode of the first transistor T1 in response to the fifth scan signal GC2.

In an embodiment, the first to ninth transistors T1 to T9 may each include a semiconductor layer including silicon. For example, the first to ninth transistors T1 to T9 may each include a semiconductor layer including low temperature polysilicon (LTPS). Polysilicon may have high electron mobility (e.g., about 100 cm²/Vs or more), low energy consumption, and excellent reliability.

As another example, the semiconductor layers of the first to ninth transistors T1 to T9 may each include an oxide of at least one material selected from indium (In), gallium (Ga), chromium (Cr), titanium (Ti), aluminum (Al), cesium (Cs), cerium (Ce), stannum (Sn), zirconium (Zr), vanadium (V), hafnium (Hf), cadmium (Cd), germanium (Ge), and zinc (Zn). For example, the semiconductor layer may be an InSnZnO (ITZO) semiconductor layer, an InGaZnO (IGZO) semiconductor layer, or the like.

As another example, some semiconductor layers of the first to ninth transistors T1 to T9 may each include LTPS, and other semiconductor layers thereof may each include an oxide semiconductor (e.g., IGZO, etc.).

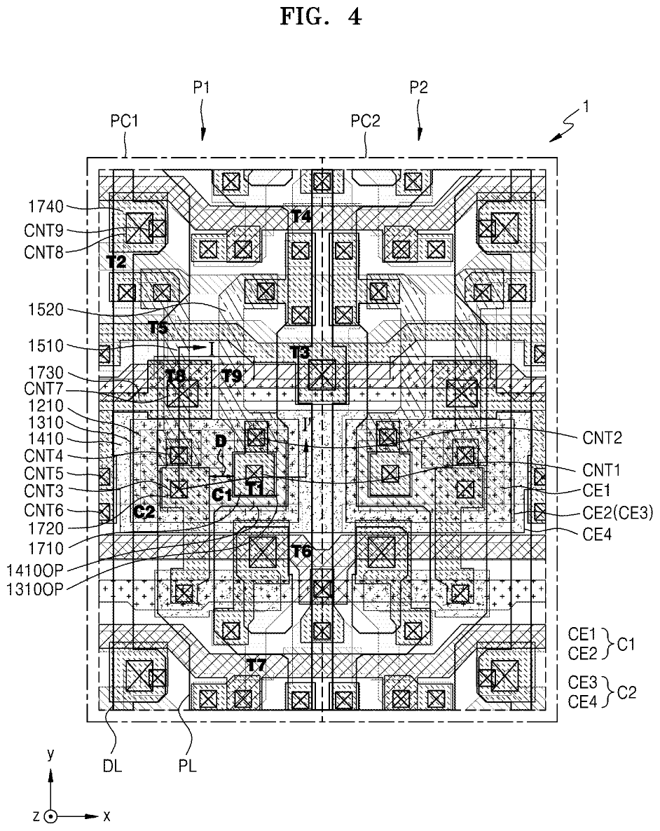

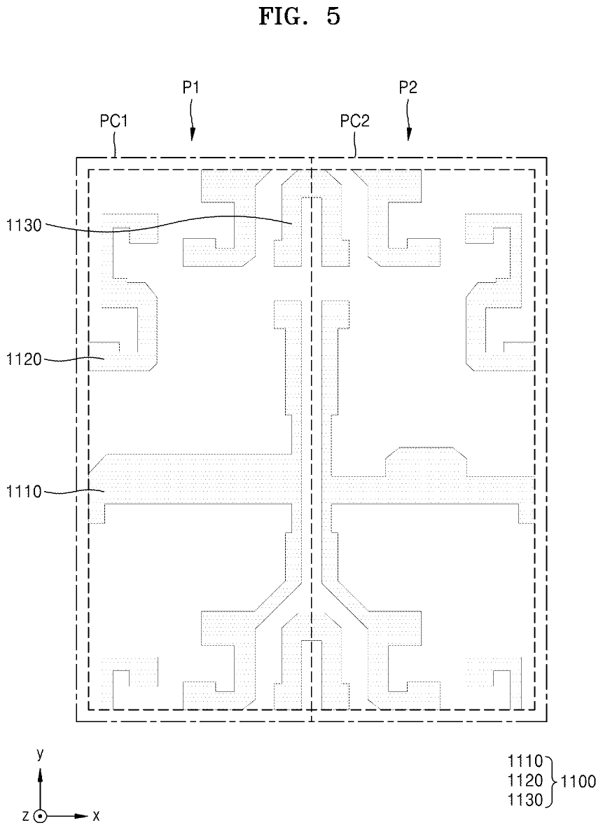

FIG. 4 is a schematic layout diagram illustrating the positions of the first to ninth transistors T1 to T9, the first capacitor C1, and the second capacitor C2 in the pixels included in the display apparatus 1 of FIG. 1. FIGS. 5 to 17 are schematic layout diagrams illustrating the layer-based configurations of the first to ninth transistors T1 to T9, the first capacitor C1, and the second capacitor C2 in the display apparatus 1 illustrated in FIG. 4, and FIG. 18 is a schematic cross-sectional view of the display apparatus 1 taken along line I-I′ of FIG. 4, according to an embodiment.

As illustrated in FIGS. 4 to 17, the display apparatus 1 may include a first pixel P1 and a second pixel P2 adjacent to each other. The first pixel P1 may include a first pixel circuit PC1, and the second pixel P2 may include a second pixel circuit PC2. Hereinafter, for descriptive convenience, some conductive pattern layers will be described with reference to the first pixel circuit PC1, but these elements may also be arranged in the second pixel circuit PC2.

The structures illustrated in FIGS. 4 to 17 may be repeatedly arranged in a first direction (e.g., x-axis direction) and/or a second direction (e.g., y-axis direction).

A substrate (see 100 of FIG. 18) may be a single glass layer. In another example, the substrate 100 may include polymer resin. The substrate 100 including the polymer resin may have a structure in which a polymer resin-containing layer and an inorganic layer are alternately stacked. In an embodiment, the substrate 100 may be flexible and may include polymer resin, such as polyethersulfone, polyarylate, polyether imide, polyethylene naphthalate, polyethylene terephthalate, polyphenylene sulfide, polyimide, polycarbonate, cellulose triacetate, or/and cellulose acetate propionate. The substrate 100 may be rigid, and may include glass including silicon dioxide (SiO₂) as a main component or may include a resin, such as reinforced plastic.

A buffer layer (see 111 of FIG. 18) including silicon oxide, silicon nitride, or silicon oxynitride may be disposed on the substrate 100. The buffer layer 111 may planarize the upper surface of the substrate 100.

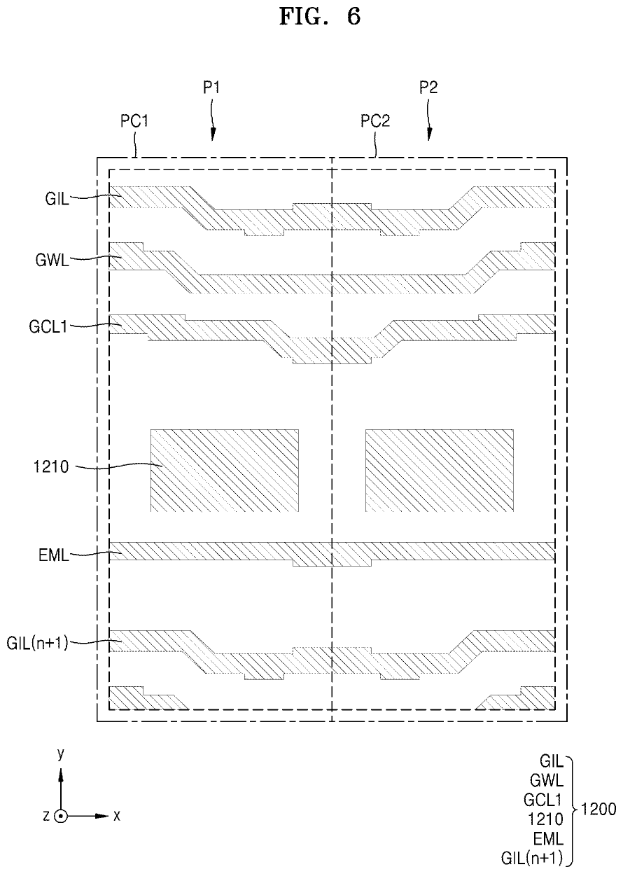

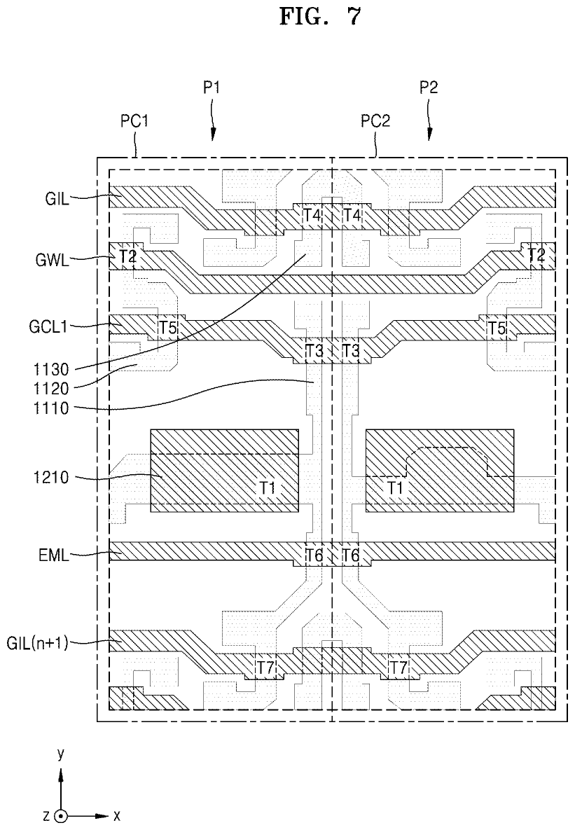

FIG. 5 illustrates a first semiconductor layer 1100, and FIG. 6 illustrates a first conductive layer 1200 disposed on the first semiconductor layer 1100. FIG. 7 illustrates the first semiconductor layer 1100 and the first conductive layer 1200 together and illustrates the arrangement of the first to seventh transistors T1 to T7.

Referring to FIGS. 5 to 7, the first semiconductor layer 1100 and the first conductive layer 1200 may overlap each other to form the first to seventh transistors T1 to T7.

As illustrated in FIG. 5, the first semiconductor layer 1100 may be disposed on the buffer layer 111. The first semiconductor layer 1100 may include a silicon semiconductor material. For example, the first semiconductor layer 1100 may include amorphous silicon or polysilicon. The first semiconductor layer 1100 may include a channel region overlapping a gate electrode, and a source region and a drain region respectively on sides (e.g., opposite sides) of the channel region. The source region and the drain region may each be a doped region to which impurities (e.g., dopants) are added.

The first semiconductor layer 1100 may include a first active pattern layer 1110, a second active pattern layer 1120, and a third active pattern layer 1130, which are spaced apart from each other.

As illustrated in FIG. 7, the first to seventh transistors T1 to T7 may be positioned along the first semiconductor layer 1100. The first transistor T1, the third transistor T3, the sixth transistor T6, and the seventh transistor T7 may be positioned in the first active pattern layer 1110. The second transistor T2 and the fifth transistor T5 may be positioned in the second active pattern layer 1120. The fourth transistor T4 may be positioned in the third active pattern layer 1130.

A first insulating layer (see 112 of FIG. 18) may be disposed on the first semiconductor layer 1100. The first insulating layer 112 may include an insulating material. For example, the first insulating layer 112 may include an inorganic insulating layer, such as silicon oxide, silicon nitride, silicon oxynitride, or aluminum oxide. The first insulating layer 112 may have a multilayer structure including the inorganic insulating layer described above. The first insulating layer 112 may be patterned along the shape of the first conductive layer 1200 disposed thereon.

As illustrated in FIG. 6, the first conductive layer 1200 may be disposed on the first semiconductor layer 1100. As illustrated in FIG. 18, the first conductive layer 1200 may be disposed on the first insulating layer 112.

The first conductive layer 1200 may include the first scan line GWL, the second scan line GCL1, the third scan line GIL, the emission control line EML, the fourth scan line GIL(n+1), and the first electrode 1210. The first conductive layer 1200 may be referred to as a first gate layer.

The first scan line GWL, the second scan line GCL1, the third scan line GIL, the emission control line EML, and the fourth scan line GIL(n+1) may extend in the first direction (e.g., x-axis direction). The first electrode 1210 may have an isolated shape. The first electrode 1210 may be disposed between the second scan line GCL1 and the emission control line EML. The first electrode 1210 may be disposed for each pixel. For example, one first electrode 1210 may be disposed in each of the first pixel P1 and the second pixel P2.

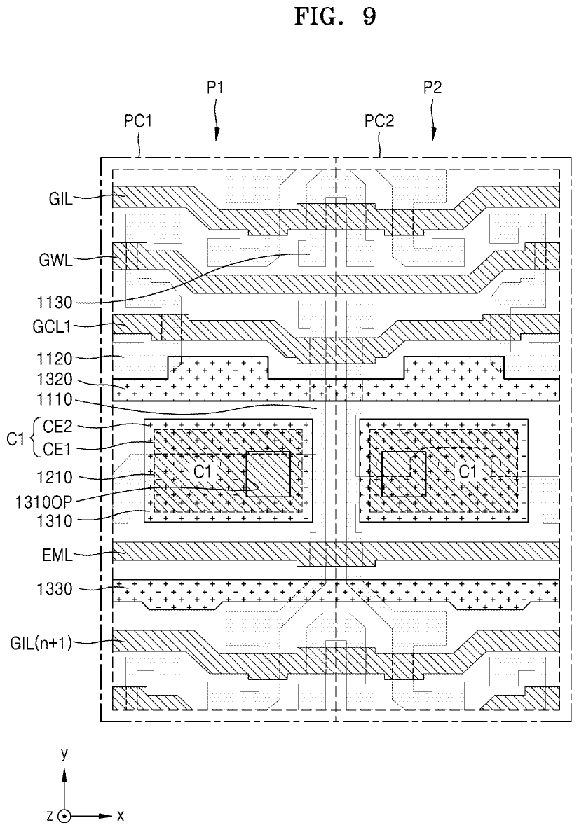

Referring to FIG. 3, the first scan line GWL may transmit the first scan signal GW. The second scan line GCL1 may transmit the second scan signal GC1. The third scan line GIL may transmit the third scan signal GI. The emission control line EML may transmit the emission control signal EM. The fourth scan line GIL(n+1) may transmit the fourth scan signal GI(n+1). The fourth scan line GIL(n+1) may be a third scan line GIL of another pixel. For example, the fourth scan line GIL(n+1) may be a third scan line GIL of another pixel adjacent to the first pixel P1 in the second direction (e.g., y-axis direction). The first electrode 1210 may be an electrode of the first capacitor C1 of FIG. 9. The first electrode 1210 may be the first lower electrode CE1 of the first capacitor C1.

The first scan line GWL, the second scan line GCL1, the third scan line GIL, the emission control line EML, the fourth scan line GIL(n+1), and the first electrode 1210 may overlap the first semiconductor layer 1100 and may function as the gate electrode.

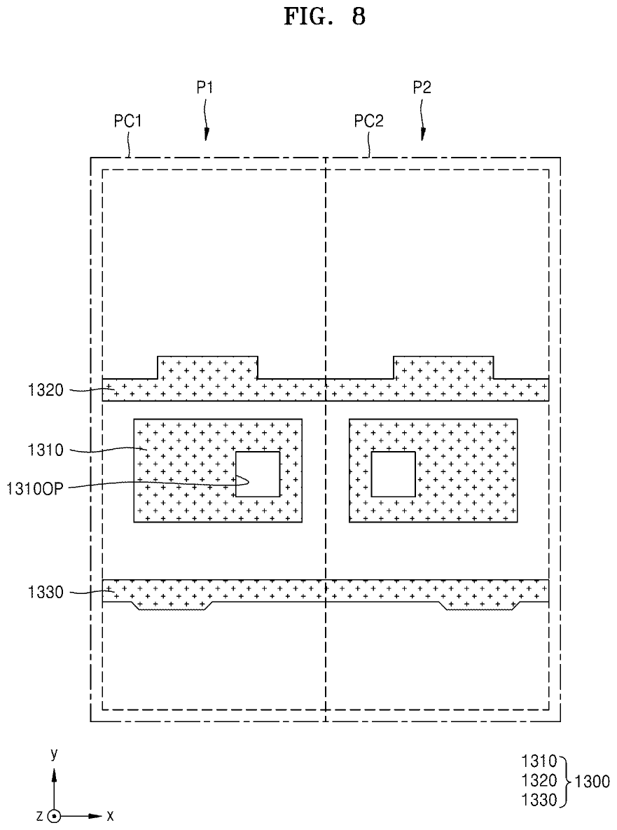

A portion in which the first scan line GWL overlaps the second active pattern layer 1120 of the first semiconductor layer 1100 may be the gate electrode of the second transistor T2. A portion in which the second scan line GCL1 overlaps the first active pattern layer 1110 of the first semiconductor layer 1100 may be the gate electrode of the third transistor T3. A portion in which the second scan line GCL1 overlaps the second active pattern layer 1120 of the first semiconductor layer 1100 may be the gate electrode of the fifth transistor T5. A portion in which the third scan line GIL overlaps the third active pattern layer 1130 of the first semiconductor layer 1100 may be the gate electrode of the fourth transistor T4. A portion in which emission control line EML overlaps the first active pattern layer 1110 of the first semiconductor layer 1100 may be the gate electrode of the sixth transistor T6. A portion in which the fourth scan line GIL(n+1) overlaps the first active pattern layer 1110 of the first semiconductor layer 1100 may be the gate electrode of the seventh transistor T7. A portion in which the first electrode 1210 overlaps the first active pattern layer 1110 of the first semiconductor layer 1100 may be the gate electrode of the first transistor T1. The first electrode 1210 may overlap a portion of an electrode of a second conductive layer (see 1300 of FIG. 8) to be described below, and may form the first capacitor C1 accordingly.

The first conductive layer 1200 may include a metal, an alloy, or a conductive metal oxide. For example, the first conductive layer 1200 may include silver (Ag), an Ag-containing alloy, molybdenum (Mo), an Mo-containing alloy, aluminum (Al), an Al-containing alloy, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The first conductive layer 1200 may have a multilayer structure.

A second insulating layer (see 113 of FIG. 18) may cover the first conductive layer 1200. The second insulating layer 113 may be disposed on the first insulating layer 112 and may cover the first conductive layer 1200. The second insulating layer 113 may include an insulating material. For example, the second insulating layer 113 may include silicon oxide, silicon nitride, silicon oxynitride, or aluminum oxide.

FIG. 8 illustrates the second conductive layer 1300, and FIG. 9 illustrates the first semiconductor layer 1100, the first conductive layer 1200, and the second conductive layer 1300 together and illustrates the arrangement of the first capacitor C1.

Referring to FIGS. 8 and 9, a portion of the first conductive layer 1200 and a portion of the second conductive layer 1300 may overlap each other to form the first capacitor C1.

The second conductive layer 1300 may be disposed on the first conductive layer 1200. As illustrated in FIG. 18, the second conductive layer 1300 may be disposed on the second insulating layer 113. The second conductive layer 1300 may include a second electrode 1310, a first transfer line 1320, and a second transfer line 1330. The second conductive layer 1300 may be referred to as a second gate layer.

The first transfer line 1320 and the second transfer line 1330 may each extend in the first direction (e.g., x-axis direction). The first transfer line 1320 and the second transfer line 1330 may be spaced apart from each other with the second electrode 1310 between the first transfer line 1320 and the second transfer line 1330. For example, the second electrode 1310 may be disposed between the first transfer line 1320 and the second transfer line 1330.

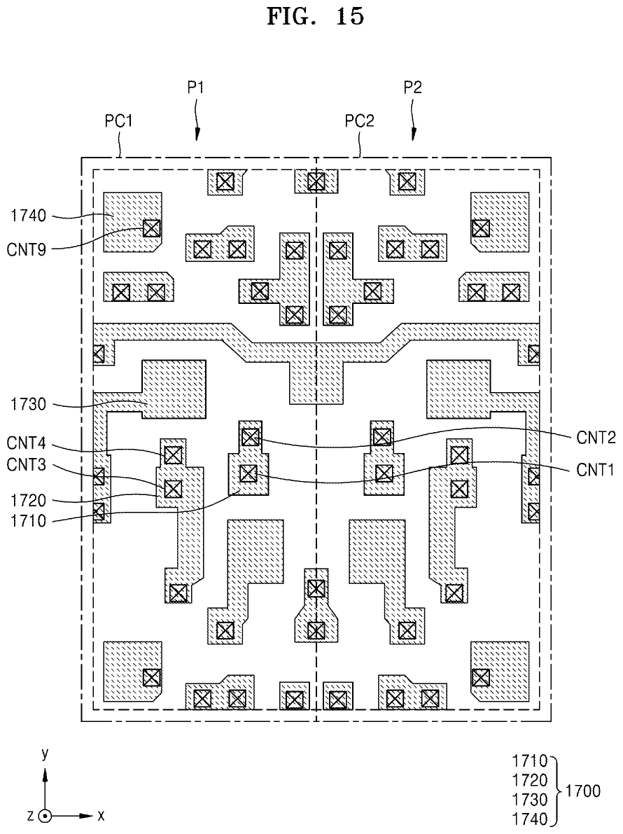

The second electrode 1310 may overlap the first electrode 1210. The second electrode 1310 may be disposed above the first electrode 1210. The second electrode 1310 may have an isolated shape. The second electrode 1310 may be disposed for each pixel. For example, one second electrode 1310 may be disposed in each of the first pixel P1 and the second pixel P2. The second electrode 1310 may have a closed opening 1310OP. A first connection electrode (see 1710 of FIG. 15) to be described below may be connected to the first electrode 1210 through the opening 1310OP of the second electrode 1310.

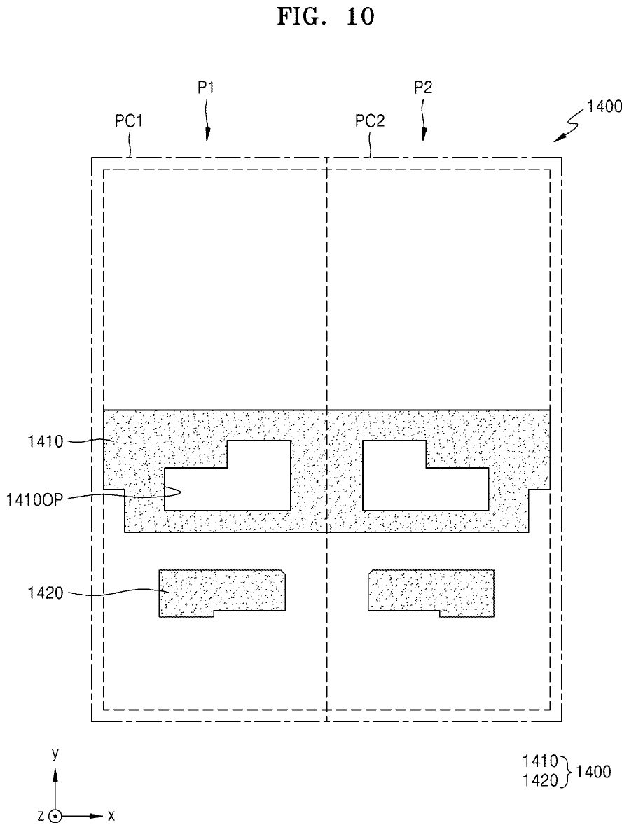

The second electrode 1310 may be an electrode of the first capacitor C1. The second electrode 1310 may be the first upper electrode CE2 of the first capacitor C1. The second electrode 1310 may overlap the first electrode 1210 of the first conductive layer 1200 and form the first capacitor C1. The second electrode 1310 may overlap a portion of an electrode of a third conductive layer (see 1400 of FIG. 10) to be described below and may form the second capacitor C2. The second electrode 1310 may be the second lower electrode CE3 of the second capacitor C2. The second electrode 1310 may function as the first upper electrode CE2 of the first capacitor C1 and may function as the second lower electrode CE3 of the second capacitor C2. For example, the second electrode 1310 may correspond to the first upper electrode CE2 of the first capacitor C1 and may correspond to the second lower electrode CE3 of the second capacitor C2.

In a case where the first capacitor C1 and the second capacitor C2 overlap each other in the positive and/or negative z-axis directions, the number of pixels that may be arranged on the xy plane may increase, compared to a case where the first capacitor C1 and the second capacitor C2 are present separately without overlapping each other. As the number of pixels arranged on the xy plane with respect to each unit area may increase, the resolution of the display apparatus may increase.

The second conductive layer 1300 may include a metal, an alloy, or a conductive metal oxide. For example, the second conductive layer 1300 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, or IZO. The second conductive layer 1300 may have a multilayer structure.

A third insulating layer (see 114 of FIG. 18) may cover the second conductive layer 1300. The third insulating layer 114 may be disposed on the second insulating layer 113 and may cover the second conductive layer 1300. The third insulating layer 114 may include an insulating material. For example, the third insulating layer 114 may include silicon oxide, silicon nitride, silicon oxynitride, or aluminum oxide.

FIG. 10 illustrates the third conductive layer 1400, and FIG. 11 illustrates the first semiconductor layer 1100, the first conductive layer 1200, the second conductive layer 1300, and the third conductive layer 1400 together and illustrates the arrangement to the second capacitor C2.

Referring to FIGS. 10 and 11, a portion of the second conductive layer 1300 and a portion of the third conductive layer 1400 may overlap each other to form the second capacitor C2.

The third conductive layer 1400 may be disposed on the second conductive layer 1300. As illustrated in FIG. 18, the third conductive layer 1400 may be disposed on the third insulating layer 114. The third conductive layer 1400 may include a third electrode 1410 and a fourth electrode 1420. The third conductive layer 1400 may be referred to as a connection conductive layer.

The third electrode 1410 may extend in the first direction (e.g., x-axis direction). The third electrode 1410 may be disposed so that a portion of the third electrode 1410 may overlap the second electrode 1310. The third electrode 1410 may be disposed above the second electrode 1310. The first electrode 1210, the second electrode 1310, and the third electrode 1410 may be sequentially disposed in a direction perpendicular to the upper surface of the substrate 100, for example, in the z-axis direction. The first electrode 1210, the second electrode 1310, and the third electrode 1410 may overlap each other in a direction perpendicular to the upper surface of the substrate 100, for example, in the z-axis direction. The fourth electrode 1420 may have an isolated shape. The fourth electrode 1420 may overlap the second transfer line 1330.

The third electrode 1410 may have a closed opening 1410OP. The third electrode 1410 may have the opening (e.g., single opening) 1410OP for each pixel. For example, the third electrode 1410 may have the opening 1410OP in the first pixel P1 and another opening 1410OP in the second pixel P2.

The opening 1410OP of the third electrode 1410 may overlap a portion of the second electrode 1310 and the opening 1310OP of the second electrode 1310 in a direction perpendicular to the upper surface of the substrate 100, for example, in the z-axis direction. For example, the opening 1410OP of the third electrode 1410 may expose a portion of the second electrode 1310 and may expose the opening 1310OP of the second electrode 1310. The opening 1410OP of the third electrode 1410 may overlap a portion of the first electrode 1210 in a direction perpendicular to the upper surface of the substrate 100, for example, in the z-axis direction. A first connection electrode (see 1710 of FIG. 15) to be described below may be connected to the first electrode 1210 through the opening 1410OP of the third electrode 1410, and a second connection electrode (see 1720 of FIG. 15) may be connected to the second electrode 1310 through the opening 1410OP of the third electrode 1410. The area (or size) of the opening 1410OP of the third electrode 1410 may be greater than the area (or size) of the opening 1310OP of the second electrode 1310. The area (or size) of the opening 1410OP of the third electrode 1410 may be substantially equal to or greater than twice the area (or size) of the opening 1310OP of the second electrode 1310.

A fourth insulating layer (see 115 of FIG. 18) may cover the third conductive layer 1400. The fourth insulating layer 115 may be disposed on the third insulating layer 114 and may cover the third conductive layer 1400. The fourth insulating layer 115 may include an insulating material. For example, the fourth insulating layer 115 may include silicon oxide, silicon nitride, silicon oxynitride, or aluminum oxide.

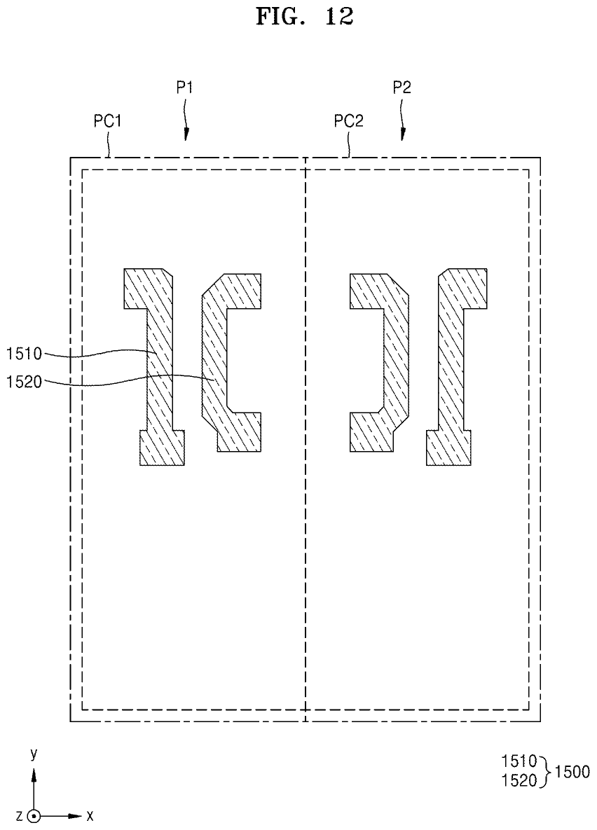

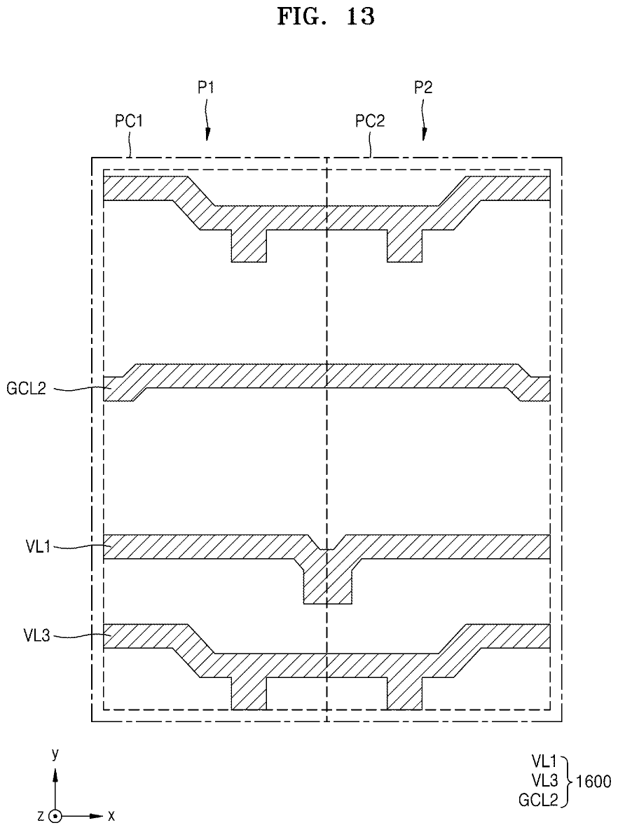

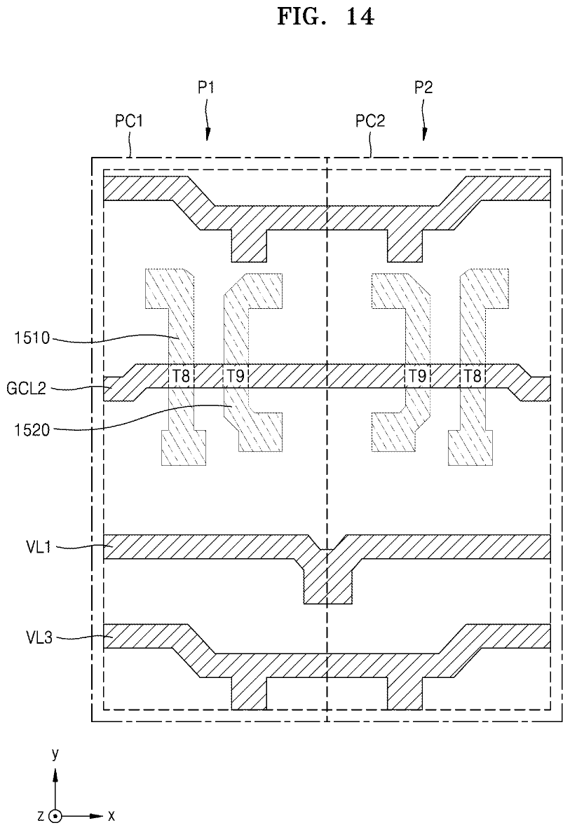

FIG. 12 illustrates a second semiconductor layer 1500, and FIG. 13 illustrates a fourth conductive layer 1600 disposed on the second semiconductor layer 1500. FIG. 14 illustrates the second semiconductor layer 1500 and the fourth conductive layer 1600 together and illustrates the arrangement of the eighth and ninth transistors T8 and T9.

Referring to FIGS. 12 to 14, the second semiconductor layer 1500 and the fourth conductive layer 1600 may overlap each other to form the eighth and ninth transistors T8 and T9.

As illustrated in FIG. 12, the second semiconductor layer 1500 may be disposed on the fourth insulating layer 115. The second semiconductor layer 1500 may be disposed on the third conductive layer 1400. The second semiconductor layer 1500 may be disposed above the third electrode 1410.

The second semiconductor layer 1500 may include an oxide semiconductor material. For example, the second semiconductor layer 1500 may include an oxide of at least one selected from In, Ga, Sn, Zr, V, Hf, Cd, Ge, Cr, Ti, Al, Cs, Ce, and Zn. For example, the second semiconductor layer 1500 may be an ITZO semiconductor layer, an IGZO semiconductor layer, or the like. As the oxide semiconductor has a wide band gap (e.g., about 3.1 eV), high carrier mobility, and low leakage current, the voltage drop may not be great even in case that the driving time is long. Accordingly, even during a low-frequency driving operation, the luminance change due to the voltage drop may not be great. The second semiconductor layer 1500 may include a channel region overlapping a gate electrode, and a source region and a drain region respectively on sides (e.g., opposite sides) of the channel region.

The second semiconductor layer 1500 may include a fourth active pattern layer 1510 and a fifth active pattern layer 1520, which are spaced apart from each other. The eighth transistor T8 may be positioned in the fourth active pattern layer 1510. The ninth transistor T9 may be positioned in the fifth active pattern layer 1520.

A fifth insulating layer (see 116 of FIG. 18) may be disposed on the second semiconductor layer 1500. The fifth insulating layer 116 may include an insulating material. For example, the fifth insulating layer 116 may include an inorganic insulating layer, such as silicon oxide, silicon nitride, silicon oxynitride, or aluminum oxide. The fifth insulating layer 116 may have a multilayer structure including the inorganic insulating layer described above.

As illustrated in FIG. 13, the fourth conductive layer 1600 may be disposed on the second semiconductor layer 1500. As illustrated in FIG. 18, the fourth conductive layer 1600 may be disposed on the fifth insulating layer 116.

The fourth conductive layer 1600 may include a fifth scan line GCL2, a first voltage line VL1, and a third voltage line VL3. The fourth conductive layer 1600 may be referred to as a third gate layer.

The fifth scan line GCL2, the first voltage line VL1, and the third voltage line VL3 may each extend in the first direction (e.g., x-axis direction).

The fifth scan line GCL2 may transmit the fifth scan signal GC2 (e.g. refer to FIG. 3). The fifth scan line GCL2 may overlap the second semiconductor layer 1500 and may function as a gate electrode. A portion in which the fifth scan line GCL2 overlaps the fourth active pattern layer 1510 of the second semiconductor layer 1500 may be the gate electrode of the eighth transistor T8. A portion in which the fifth scan line GCL2 overlaps the fifth active pattern layer 1520 of the second semiconductor layer 1500 may be the gate electrode of the ninth transistor T9.

The first voltage line VL1 may transmit the first initialization voltage V_{INT} (e.g. refer to FIG. 3), and the third voltage line VL3 may transmit the second initialization voltage V_{AINT} (e.g. refer to FIG. 3).

The fourth conductive layer 1600 may include a metal, an alloy, or a conductive metal oxide. For example, the fourth conductive layer 1600 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, or IZO. The fourth conductive layer 1600 may have a multilayer structure.

A sixth insulating layer (see 117 of FIG. 18) may cover the fourth conductive layer 1600. The sixth insulating layer 117 may be disposed on the fifth insulating layer 116 and may cover the fourth conductive layer 1600. The sixth insulating layer 117 may include an insulating material. For example, the sixth insulating layer 117 may include silicon oxide, silicon nitride, silicon oxynitride, or aluminum oxide.

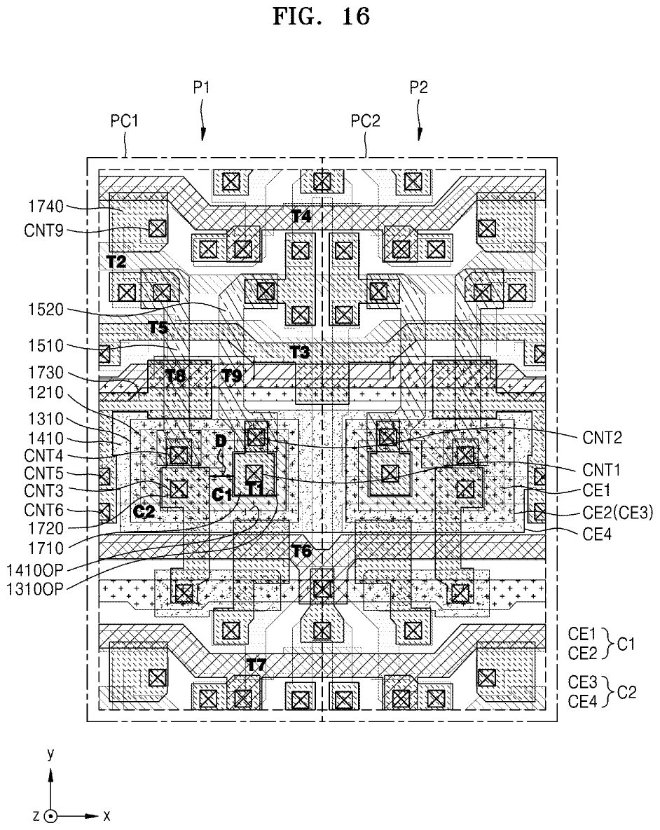

FIG. 15 illustrates a fifth conductive layer 1700, and FIG. 16 illustrates the first semiconductor layer 1100, the first conductive layer 1200, the second conductive layer 1300, the third conductive layer 1400, the second semiconductor layer 1500, the fourth conductive layer 1600, and the fifth conductive layer 1700 together.

As illustrated in FIG. 15, the fifth conductive layer 1700 may include a first connection electrode 1710, a second connection electrode 1720, a third connection electrode 1730, and a fourth connection electrode 1740. For example, the first connection electrode 1710, the second connection electrode 1720, the third connection electrode 1730, and the fourth connection electrode 1740 may be arranged on the same layer. The fifth conductive layer 1700 may be disposed on the fourth conductive layer 1600. The fifth conductive layer 1700 may be disposed above the fourth conductive layer 1600. The fifth conductive layer 1700 may be disposed on the sixth insulating layer 117. The fifth conductive layer 1700 may be referred to as a first source/drain layer or a connection electrode layer.

The first connection electrode 1710 may be connected to the first electrode 1210 through a contact hole CNT1. For example, the contact hole CNT1 may extend to pass through the opening 1310OP of the second electrode 1310 and the opening 1410OP of the third electrode 1410 in the z-axis direction. The contact hole CNT1 may be filled with a via layer extending from the first connection electrode 1710 to the first electrode 1210. The first connection electrode 1710 may be connected to the first electrode 1210 through the opening 1310OP of the second electrode 1310 and the opening 1410OP of the third electrode 1410. At least a portion of the first connection electrode 1710 may overlap the first electrode 1210 in a direction perpendicular to the upper surface of the substrate 100, for example, in the z-axis direction. At least a portion of the first connection electrode 1710 may overlap the opening 1310OP of the second electrode 1310 and may overlap the opening 1410OP of the third electrode 1410. A portion of the first connection electrode 1710 may be within the opening 1310OP of the second electrode 1310. A portion of the first connection electrode 1710 may be within the opening 1410OP of the third electrode 1410.

The first connection electrode 1710 may be connected to the second semiconductor layer 1500 through a contact hole CNT2. The first connection electrode 1710 may be connected to the fifth active pattern layer 1520 of the second semiconductor layer 1500 through the contact hole CNT2. The first connection electrode 1710 may electrically connect the second semiconductor layer 1500 to the first electrode 1210. The first connection electrode 1710 may electrically connect the fifth active pattern layer 1520 of the second semiconductor layer 1500 to the first electrode 1210.

The second connection electrode 1720 may be connected to the second electrode 1310 through a contact hole CNT3. For example, the contact hole CNT3 may extend to pass through the opening 1410OP of the third electrode 1410 in the z-axis direction. The contact hole CNT3 may be filled with a via layer extending from the second connection electrode 1720 to the second electrode 1310. For example, the contact hole CNT1 and the contact hole CNT3 may be spaced apart from each other inside the opening 1410OP of the third electrode 1410. The second connection electrode 1720 may be connected to the second electrode 1310 through the opening 1410OP of the third electrode 1410. At least a portion of the second connection electrode 1720 may overlap the second electrode 1310 in a direction perpendicular to the upper surface of the substrate 100, for example, in the z-axis direction. At least a portion of the second connection electrode 1720 may overlap the opening 1410OP of the third electrode 1410 and may not overlap the opening 1310OP of the second electrode 1310. A portion of the second connection electrode 1720 may be within the opening 1410OP of the third electrode 1410.

The second connection electrode 1720 may be connected to the second semiconductor layer 1500 through a contact hole CNT4. The second connection electrode 1720 may be connected to the fourth active pattern layer 1510 of the second semiconductor layer 1500 through the contact hole CNT4. The second connection electrode 1720 may electrically connect the second semiconductor layer 1500 to the second electrode 1310. The second connection electrode 1720 may electrically connect the fourth active pattern layer 1510 of the second semiconductor layer 1500 to the second electrode 1310.

The first connection electrode 1710 and the second connection electrode 1720 may be spaced apart from each other within the opening 1410OP of the third electrode 1410. An insulating structure including the third insulating layer 114, the fourth insulating layer 115, the fifth insulating layer 116, and the sixth insulating layer 117 may be disposed between the first connection electrode 1710 and the second connection electrode 1720 in a plan view. The third conductive layer 1400 may not be disposed between the first connection electrode 1710 and the second connection electrode 1720 in a plan view. For example, only the insulating structure may be disposed between the first connection electrode 1710 and the second connection electrode 1720 in a plan view.

As the opening 1410OP of the third electrode 1410 is formed so that the first connection electrode 1710 and the second electrode 1310 may be respectively connected to the first electrode 1210 and the second connection electrode 1720, a distance D between the first connection electrode 1710 and the second connection electrode 1720 may be formed at a minimum interval (or minimum distance) in a process. In an embodiment, the distance D between the first connection electrode 1710 and the second connection electrode 1720 may be reduced, compared to the case where the openings in which the first connection electrode 1710 and the second connection electrode 1720 are arranged are separately formed. As the distance D between the first connection electrode 1710 and the second connection electrode 1720 may be formed at a minimum interval (or minimum distance) in a process, the degree of freedom in designing the conductive layers may increase and the resolution of the display apparatus 1 may increase.

The first connection electrode 1710 and the second connection electrode 1720 may be arranged on the same layer. The first connection electrode 1710 and the second connection electrode 1720 may be disposed above the third conductive layer 1400. The first connection electrode 1710 and the second connection electrode 1720 may be disposed above the third electrode 1410. The first connection electrode 1710 and the second connection electrode 1720 may be disposed above the second semiconductor layer 1500.

The fifth conductive layer 1700 may include a metal, an alloy, or a conductive metal oxide. For example, the fifth conductive layer 1700 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, or IZO. The fifth conductive layer 1700 may have a multilayer structure.

A seventh insulating layer (see 118 of FIG. 18) may cover the fifth conductive layer 1700. The seventh insulating layer 118 may be disposed on the sixth insulating layer 117 and may cover the fifth conductive layer 1700. The seventh insulating layer 118 may include an insulating material. The seventh insulating layer 118 may include a single layer or layers including an organic material and may provide a flat upper surface. For example, the seventh insulating layer 118 may include general-purpose polymer (e.g., benzocyclobutene (BCB), polyimide, hexamethyldisiloxane (HMDSO), polymethylmethacrylate (PMMA), or polystyrene (PS)), polymer derivatives having a phenolic group, acrylic polymer, imide-based polymer, aryl ether-based polymer, amide-based polymer, fluorine-based polymer, p-xylene-based polymer, vinyl alcohol-based polymer, or any blend thereof.

FIG. 17 illustrates a sixth conductive layer 1800. The sixth conductive layer 1800 may be disposed on the fifth conductive layer 1700. The sixth conductive layer 1800 may be disposed above the fifth conductive layer 1700. The sixth conductive layer 1800 may be disposed on the seventh insulating layer 118. The sixth conductive layer 1800 may be referred to as a second source/drain layer.

The sixth conductive layer 1800 may include the driving voltage line PL and the data line DL. The driving voltage line PL may transmit the driving voltage ELVDD (e.g. refer to FIG. 3), and the data line DL may transmit the data voltage Dm (e.g. refer to FIG. 3).

The driving voltage line PL may be connected to the third connection electrode 1730 through a contact hole CNT7. The third connection electrode 1730 may be connected to the third electrode 1410 through a contact hole CNT5 and connected to the first active pattern layer 1110 of the first semiconductor layer 1100 through a contact hole CNT6. The third connection electrode 1730 may electrically connect the driving voltage line PL to the third electrode 1410. The third connection electrode 1730 may electrically connect the driving voltage line PL to the first active pattern layer 1110.

The data line DL may be connected to the fourth connection electrode 1740 through a contact hole CNT8. The fourth connection electrode 1740 may be connected to the second active pattern layer 1120 of the first semiconductor layer 1100 through a contact hole CNT9. The fourth connection electrode 1740 may electrically connect the data line DL to the second active pattern layer 1120.

An eighth insulating layer (see 119 of FIG. 18) may cover the sixth conductive layer 1800. The eighth insulating layer 119 may be disposed on the seventh insulating layer 118 and may cover the sixth conductive layer 1800. The eighth insulating layer 119 may include an insulating material. The eighth insulating layer 119 may include a single layer or layers including an organic material and may provide a flat upper surface. For example, the eighth insulating layer 119 may include general-purpose polymer (e.g., BCB, polyimide, HMDSO, PMMA, or PS), polymer derivatives having a phenolic group, acrylic polymer, imide-based polymer, aryl ether-based polymer, amide-based polymer, fluorine-based polymer, p-xylene-based polymer, vinyl alcohol-based polymer, or any blend thereof.

For example, an organic light-emitting diode including an anode electrode, an emission layer, and a cathode electrode may be disposed on the eighth insulating layer 119. For example, the anode electrode, a pixel defining layer including an organic insulating material, the emission layer, and the cathode electrode may be sequentially disposed on the eighth insulating layer 119 in this stated order.

The display apparatus 1 has been described above, but embodiments are not limited thereto. For example, a method of manufacturing the display apparatus 1 may be included in the scope of the disclosure.

According to various embodiments, the distance between connection electrodes may be reduced by forming an opening in an electrode of an upper capacitor among two capacitors overlapping each other in a vertical direction and arranging the two connection electrodes in the opening. As the distance between the connection electrodes decreases, the degree of freedom in wiring design may increase, and thus, the resolution of the display apparatus may increase. The scope of the disclosure is not limited by such an effect.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display apparatus comprising:
a substrate;
a first transistor comprising a first semiconductor layer on the substrate and a first electrode overlapping the first semiconductor layer;
a first capacitor comprising the first electrode and a second electrode, the second electrode overlapping the first electrode;
a second capacitor comprising the second electrode and a third electrode, the third electrode overlapping the second electrode;
a first connection electrode and a second connection electrode disposed on the third electrode, wherein
the third electrode comprises a first opening, and
a portion of the first connection electrode and a portion of the second connection electrode are adjacent to each other, are spaced apart from each other, and overlap the first opening.

2. The display apparatus of claim 1, wherein
the first connection electrode is electrically connected to the first electrode, and
the second connection electrode is electrically connected to the second electrode.

3. The display apparatus of claim 1, wherein
the second electrode comprises a second opening overlapping the first opening in a direction perpendicular to an upper surface of the substrate, and
a portion of the first connection electrode overlaps the second opening.

4. The display apparatus of claim 3, wherein a size of the first opening is greater than a size of the second opening.

5. The display apparatus of claim 3, wherein a size of the first opening is substantially equal to or greater than twice a size of the second opening.

6. The display apparatus of claim 1, wherein
the second electrode is disposed above the first electrode,
the third electrode is disposed above the second electrode, and
the first connection electrode and the second connection electrode are disposed above the third electrode.

7. The display apparatus of claim 1, wherein the first connection electrode and the second connection electrode are disposed on a same layer.

8. The display apparatus of claim 1, further comprising:
a second semiconductor layer disposed above the third electrode; and
a second transistor comprising a gate electrode disposed above the second semiconductor layer, the gate electrode overlapping the second semiconductor layer.

9. The display apparatus of claim 8, wherein
the first semiconductor layer comprises a silicon semiconductor material, and
the second semiconductor layer comprises an oxide semiconductor material.

10. The display apparatus of claim 8, wherein the first connection electrode and the second connection electrode are disposed above the second semiconductor layer.

11. The display apparatus of claim 8, wherein the second connection electrode electrically connects the second electrode to the second semiconductor layer.

12. The display apparatus of claim 8, wherein
the second semiconductor layer comprises a first active pattern layer and a second active pattern layer,
the first active pattern layer is electrically connected to the second electrode through the second connection electrode, and
the second active pattern layer is electrically connected to the first electrode through the first connection electrode.

13. A display apparatus comprising:
a substrate;
a first semiconductor layer disposed above the substrate;
a first gate layer disposed above the first semiconductor layer, the first gate layer comprising a first electrode;
a second gate layer disposed above the first gate layer, the second gate layer comprising a second electrode overlapping the first electrode in a direction toward an upper surface of the substrate;
a connection conductive layer disposed above the second gate layer, the connection conductive layer comprising a third electrode overlapping the second electrode and having a first opening; and
a connection electrode layer disposed above the connection conductive layer, the connection electrode layer comprising a first connection electrode and a second connection electrode,
wherein a portion of the first connection electrode and a portion of the second connection electrode are adjacent to each other, are spaced apart from each other, and overlaps the first opening.

14. The display apparatus of claim 13, wherein
the second electrode comprises a second opening overlapping the first opening in a direction perpendicular to the upper surface of the substrate, and
a portion of the first connection electrode overlaps the second opening.

15. The display apparatus of claim 14, wherein
the first connection electrode is electrically connected to the first electrode through the first opening and the second opening, and
the second connection electrode is electrically connected to the second electrode through the first opening.

16. The display apparatus of claim 14, wherein a size of the first opening is greater than a size of the second opening.

17. The display apparatus of claim 14, wherein a size of the first opening is substantially equal to or greater than twice a size of the second opening.

18. The display apparatus of claim 13, further comprising:
a second semiconductor layer disposed above the connection conductive layer and disposed below the connection electrode layer; and
a third gate electrode layer disposed above the second semiconductor layer and disposed below the connection electrode layer.

19. The display apparatus of claim 18, wherein
the first semiconductor layer comprises a silicon semiconductor material, and
the second semiconductor layer comprises an oxide semiconductor material.

20. The display apparatus of claim 18, wherein
the second semiconductor layer comprises a first active pattern layer and a second active pattern layer,
the first active pattern layer is electrically connected to the second electrode through the second connection electrode, and
the second active pattern layer is electrically connected to the first electrode through the first connection electrode.
